(19) United States
(12) Patent Application Publication
(10) Pub. No.: US 2002/0100954 A1
(43) Pub. Date: Aug. 1, 2002

(54) Circuit for generating an asynchronous signal pulse

(76) Inventor: Ronalf Kramer, Munchen (DE)

Correspondence Address: JENKINS & WILSON, PA, 3100 TOWER BLVD, SUITE 1400, DURHAM, NC, 27707, US

(21) Appl. No.: 10/052,652

(22) Filed: Jan. 18, 2002

(30) Foreign Application Priority Data
Jan. 24, 2001 (DE) 101 030 52.5

(51) Int. Cl. H01L 29/00

(52) U.S. Cl. 257/516; 257/577

(57) ABSTRACT

In order to generate a pulsed signal with a desired active state without a great outlay on circuitry, the circuit according to the invention is characterized by a first and a second transistor (2, 3) in the integrated circuit, which are connected in series between a supply potential (U_{DD}) and ground (GND), firstly a control pulse (A) having the predetermined duration being present at a control connection (G1) of the first transistor (2) and then a control pulse (B) being present at a control connection (G2) of the second transistor (3), with the result that, for the predetermined duration, firstly the first transistor (2) and then the second transistor (3) is turned on, and a resistor (6, 7) for the definition of the active signal state, which is connected outside the integrated circuit in parallel with one of the two transistors (2, 3) in the integrated circuit either between the supply potential (U_{DD}) and the connecting point (4) or between ground (GND) and the connecting point (4).

A problem that often arises in the conventional circuits is that it is necessary to define in an obligatory manner whether a signal is active high or active low as early as in the design of the circuit. In particular, this is important if the corresponding signal is later to be used in a circuit as reset signal or as watchdog signal. If the active state of the signal is not chosen correctly, the signal cannot be used and system deadlocks can occur, which have a fatal effect precisely in the case of watchdog or reset signals.

The definition of the active state of a signal output by the circuit can be postponed until the concrete use of the circuit if there is the possibility of subsequent programming of the circuit. To that end, by way of example, it is possible to use a register in the circuit. However, this has the disadvantageous effect that the circuit has to be configured in a considerably more complex fashion.

A further possibility for postponing the definition of the active state of the signal output by the circuit until the installation of the circuit consists in both an active high and an active low signal being output by the circuit. When the circuit is installed, one or the other signal can be tapped off. However, this possibility has the disadvantage that two connections (pads) instead of only one connection have to be provided in the circuit for the signals to be output. This is particularly disturbing in the case of integrated circuits, in which, depending on the package, only a limited number of connections are available.

It is an object of the present invention to provide a circuit which can be used to generate a pulsed signal with the desired active state without a great outlay on circuitry and without the problems as in the prior art.

This object is achieved by means of the circuit according to claim 1. The subclaims relate to preferred embodiments of the invention.

The invention's circuit for generating an asynchronous signal pulse having a predetermined duration at an output of an integrated circuit successively outputs two pulses, one of which is used on the circuit board depending on external circuitry. As a result, an active-high and active-low pulse is provided at the output without special settings such as programming of the circuit. A pull-down or a pull-up resistor on the board containing the integrated circuit defines which of the two pulses is used. The circuit according to the invention comprises a first and a second transistor in the integrated circuit, which are connected in series between a supply potential U_{DD} and ground GND, an output potential being tapped off at their connecting point and a control pulse having the predetermined duration in each case being present at their control connection, with the result that, for the predetermined duration, either the first transistor or the second transistor is turned on and the connecting point is either at the supply potential U_{DD} or at ground GND, and a resistor for the definition of the active signal state, which is connected outside the integrated circuit in parallel with one of the two transistors in the integrated circuit either between the supply potential U_{DD} and the connecting point or between ground GND and the connecting point.

A waiting time is preferably provided between the first control pulse and the second control pulse. The second control pulse is preferably generated from the first control pulse by an inverter delay device.

In a further preferred embodiment of the invention, the first transistor is a P-channel MOS transistor and the second transistor is an N-channel MOS transistor, the control connection of the first transistor being inverted. In particular, the first transistor and the second transistor can form a CMOS inverter with independent control gate connections.

One advantage of the invention is that the external circuitry of the integrated circuit takes up little space on the board in the case of the solution according to the invention.

Further features and advantages of the invention emerge from the following description of exemplary embodiments.

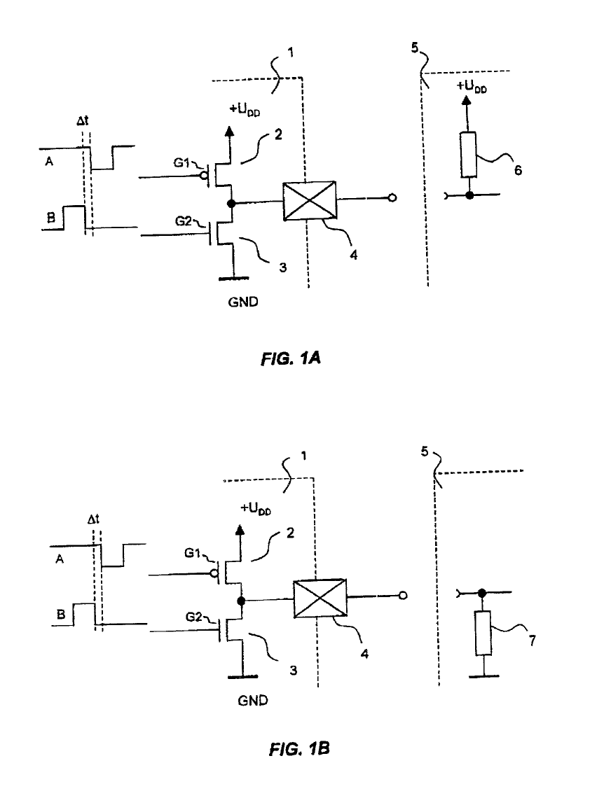

FIGS. 1A and 1B each show an embodiment of the invention.

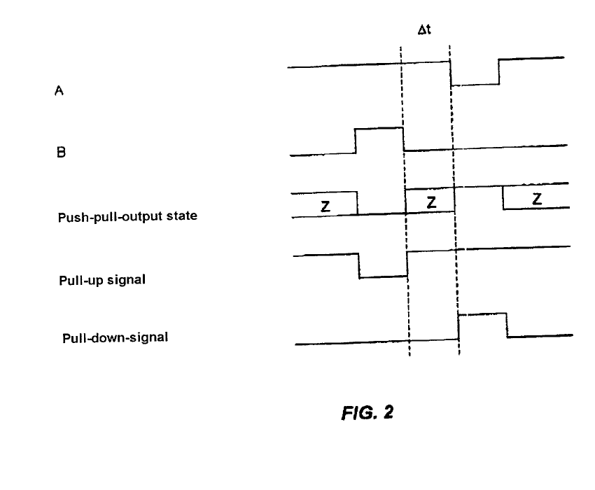

FIG. 2 shows the time profile of the input and output signals of the integrated circuit in accordance with FIGS. 1A and 1B.

The circuit—shown in FIG. 1—for generating an asynchronous signal pulse at an output of an integrated circuit 1, which pulse has a predetermined duration and, in particular, can be used as reset or watchdog signal, comprises a first transistor 2 and a second transistor 3. The two transistors 2 and 3 are part of the integrated circuit. In FIG. 1, the integrated circuit 1 is indicated by two broken lines which represent the boundary of the integrated circuit 1. In the embodiment of the invention illustrated, the first transistor 2 is a P-channel MOS transistor (with a small circle at the gate connection) and the second transistor 3 is an N-channel MOS transistor. The construction of the circuit thus essentially corresponds to a CMOS inverter in which, however, the control gate connections of the transistors remain independently drivable.

The transistors 2 and 3 are connected in series between a supply potential U_{DD} and ground GND. The source connection of the first transistor 2 is at a supply potential U_{DD} and the drain connection of the first transistor 2 is connected to the drain connection of the second transistor 3. The source connection of the second transistor 3 is at ground GND. A first control signal A is present at the gate G1 of the first transistor 2 and a second control signal B is present at the gate G2 of the second transistor 3.

The connecting point of the drain connection of the first transistor 2 and the drain connection of the second transistor 3 is connected to a connection pad 4. If one of the two transistors 2 and 3 is turned on, the connection pad 4 is connected to the respective potential, and it is at a defined output potential which can be tapped off externally.

If none of the two transistors 2 and 3 is in the on state, then the connection pad 4 is isolated in a high-impedance manner both from supply potential U_{DD} and from ground GND, with the result that the connection pad 4 “floats” and the push-pull stage comprising the two transistors 2 and 3 forms a tristate output.

In order to turn on one of the two transistors 2 and 3, a respective control pulse A or B is applied to their control terminal G1 or G2. The control pulse A and B in each case has a predetermined duration which corresponds to the desired duration of the output signal at the pad 4 and depends on the requirements made e.g. of a reset pulse for further components (not illustrated) on the circuit board. Either the first transistor 2 or the second transistor 3 is in the on state for this predetermined duration of the control pulse A or B. Accordingly, the connection pad 4 is either at the supply potential U_{DD} or at ground GND.

According to the invention, firstly a first control pulse is applied to one of the two control electrodes. Afterward, a second control pulse is applied to the second of the two control electrodes, with the result that the two transistors turn on successively. In the embodiments illustrated here, firstly the second control pulse B is applied to the second control gate G2 and then the first control pulse A is applied to the first control gate G1. The connection pad 4 is therefore at the supply potential U_{DD} for a duration determined by the control pulse A, and at ground GND for a duration determined by the control pulse B. (In principle, the duration of the two control pulses A and B can differ, but in practice they will both have an identical duration.) If both control pulses A and B are returned again to a value at which the transistors 2 and 3 turn off, the pad 4 “floats” and therefore no longer influences the external components (not illustrated), connected to the pad 4, on the circuit board.

In the application, generally only one of these potentials U_{DD} or GND (active low or active high) is required. The selection of the required potential from the two potentials that are successively present at the pad 4 is effected by a pull-down or pull-up resistor. A board 5 with a pull-up resistor 6 is shown in FIG. 1A and a board 5 with a pull-down resistor 7 is shown in FIG. 1B.

As can be seen from FIG. 1A, the pull-up resistor 6, for the definition of the inactive signal state on the circuit board, is connected in parallel with the transistor 2 in the integrated circuit, so that it pulls the pad 4 to the supply potential U_{DD}. This construction will be chosen, therefore, if an active-low (reset) signal is required at the output of the integrated circuit.

The pull-down resistor 7 in FIG. 1B is connected in parallel with the transistor 3 in the integrated circuit between ground GND and the pad 4 so that it pulls the pad 4 to ground. This construction will be chosen if an active-high (reset) signal is required at the output of the integrated circuit.

The time profile of the signals mentioned above is summarized in FIG. 2. The first gate connection G1 is initially at an inactive level. At a specific instant, a control pulse A having a predetermined duration is applied to the gate G1. Analogously, the second gate G2 is initially at an inactive level. At a specific instant, a control pulse B having a predetermined duration is applied to the gate G2. In the embodiment according to FIG. 2, the first control pulse A temporally succeeds the second control pulse B. A waiting time Δt is provided between the second control pulse B and the first control pulse A in order to reliably preclude an overlapping of the two pulses A and B and hence a short circuit of supply potential U_{DD} and ground GND.

Such a sequence of two successive control pulses A and B at the gates of the transistors 2 and 3 can be generated particularly simply by means of an inverter delay device (not illustrated). In this case, the first control pulse A is generated from the second control pulse B by the second control pulse B being applied simultaneously both to the gate 2 and to the inverter delay device. If the edge rises at the gate G2, then it also rises at the inverter delay device. If the second control pulse B at the gate G2 falls again, the delayed and inverted rising edge is output as control pulse A to the first gate G1 by the inverter delay device. In this case, it goes without saying that the duration of the second control pulse B must be chosen such that the second control pulse B is returned to its original level again when the inverter delay device outputs the first control pulse A. In order to reliably avoid a short circuit, in this case it is possible to provide a time interval between the two pulses A and B in which the two pulses A and B do not overlap.

Below the signals A and B, FIG. 2 shows the output state of the push-pull stage at the pad 4 dependent on the state of the pulses A and B at the gates G1 and G2. As long as the two gates G1 and G2 are at an inactive potential, the pad 4 “floats” i.e. the potential of the pad 4 is indeterminate, which is indicated by Z in FIG. 2.

A pull-up resistor 6 or a pull-down resistor 7 on the board, outside the integrated circuit, generates from the push-pull output state the desired asynchronous signal pulse of the two possible asynchronous signal pulses which are illustrated in the bottom two lines in FIG. 2.

Even though the invention has been described on the basis of MOSFET transistors, it is clear to the person skilled in the art that it can also be realized using bipolar transistors.

1. A circuit for generating an asynchronous signal pulse having a predetermined duration at an output of an integrated circuit,
which has
a first and a second transistor (2, 3) in the integrated circuit, which are connected in series between a supply potential (U_{DD}) and ground (GND), firstly a control pulse (A) having the predetermined duration being present at a control connection (G1) of the first transistor (2) and then a control pulse (B) being present at a control connection (G2) of the second transistor (3), with the result that, for the predetermined duration, firstly the first transistor (2) and then the second transistor (3) is turned on and the connecting point (4) is firstly at the supply potential (U_{DD}) and then at ground (GND), and a resistor (6, 7) for the definition of the active signal state, which is connected outside the integrated circuit in parallel with one of the two transistors (2, 3) in the integrated circuit either between the supply potential (U_{DD}) and the connecting point (4) or between ground (GND) and the connecting point (4).

2. The circuit as claimed in claim 1,
wherein
a waiting time (At) is provided between the first control pulse (A) and the second control pulse (B), in which the two pulses do not overlap.

3. The circuit as claimed in claim 1 or 2,
wherein
one of the two control pulses (B) is generated from the other of the two control pulses (A) by an inverter delay device.

4. The circuit as claimed in one of the preceding claims,
wherein
the first transistor (2) is a P-channel MOS transistor and the second transistor (3) is an N-channel MOS transistor, the control connection (G1) of the first transistor being inverted.

5. The circuit as claimed in claim 4,
wherein
the first transistor (2) and the second transistor (3) form a CMOS inverter with independent control gate connections.
